(19) United States
(12) Patent Application Publication
(10) Pub. No.: US 2026/0198283 A1
(43) Pub. Date: Jul. 9, 2026

(54) MEMORY DEVICES WITH MULTIPLE TRACKS FORMING ACCESS LINE AND METHODS FOR MANUFACTURING THE SAME

(71) Applicant: Taiwan Semiconductor Manufacturing Company, Ltd., Hsinchu (TW)

(72) Inventors: Zheng-Jun Lin, Hsinchu City (TW); Sheng-Hung Shih, Hsinchu City (TW); Chung-Cheng Chou, Hsinchu City (TW)

(73) Assignee: Taiwan Semiconductor Manufacturing Company, Ltd., Hsinchu (TW)

(21) Appl. No.: 19/180,906

(22) Filed: Apr. 16, 2025

Related U.S. Application Data
(60) Provisional application No. 63/742,244, filed on Jan. 6, 2025.

(51) Int. Cl. H10W 20/42; G11C 5/06; H10B 63/00; H10W 20/00; H10W 20/40; H10W 20/41; H10W 20/43

(52) U.S. Cl. CPC H10W 20/42; G11C 5/063; H10B 63/30; H10B 63/84; H10W 20/0693; H10W 20/43; H10W 20/435; H10W 20/498

(57) ABSTRACT

A memory device includes a plurality of memory cells, each of the plurality of memory cells including a resistive element and a transistor connected in series between a first access line and a second access line. The first access line includes at least a first metal track disposed in a first one of a plurality of metallization layers over a substrate, and a second metal track disposed in a second one of the plurality of metallization layers. The second access line includes at least a third metal track disposed in a third one of the plurality of metallization layers, and a fourth metal track disposed in a fourth one of the plurality of metallization layers. The second metallization layer is disposed over the fourth metallization layer, the fourth metallization layer is disposed over the third metallization layer, and the third metallization layer is disposed over the first metallization layer.

### CROSS-REFERENCE TO RELATED APPLICATION

This application claims priority to and the benefit of U.S. Provisional Application No. 63/742,244, filed Jan. 6, 2025, entitled “NOVEL RRAM SL STITCH FOR RESISTANCE REDUCTION,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device, in accordance with some embodiments.

FIG. 2 illustrates a schematic diagram a memory cell of the memory device of FIG. 1, in accordance with some embodiments.

FIG. 3 illustrates a schematic diagram of a portion of the memory device of FIG. 1, in accordance with some embodiments.

FIG. 4 illustrates a schematic diagram of a portion of the memory device of FIG. 1, in accordance with some embodiments.

FIG. 5 illustrates a layout for forming access lines of the memory device configured with the schematic diagram of FIG. 3, in accordance with some embodiments.

FIG. 6 illustrates a layout for forming access lines of the memory device configured with the schematic diagram of FIG. 4, in accordance with some embodiments.

FIG. 7 illustrates a cross-sectional view of a semiconductor device formed based on the layout of FIG. 5, in accordance with some embodiments.

FIG. 8 illustrates a top view of the semiconductor device shown in FIG. 7, in accordance with some embodiments.

FIG. 9 and FIG. 10 illustrate arrangements among one or more strap regions and a memory array, respectively, in accordance with some embodiments.

FIG. 11 illustrates a cross-sectional view of a semiconductor device formed based on the layout of FIG. 5, in accordance with some embodiments.

FIG. 12 and FIG. 13 illustrate arrangements among one or more strap regions and a memory array, respectively, in accordance with some embodiments.

FIG. 14 illustrates a flowchart of an example method for forming a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many modern day electronic devices include electronic memory devices configured to store data. An electronic memory device is typically a volatile memory device or non-volatile memory device. The volatile memory device stores data when it is powered, while the non-volatile memory device is able to store data when power is removed. A resistive random access memory (RRAM) device is one promising candidate for a next generation non-volatile memory technology. The RRAM device has a simple structure, consumes a small cell area, has a low switching voltage and fast switching times, and is compatible with complementary-metal-oxide-semiconductor (CMOS) fabrication processes.

Memory cells of a RRAM device (typically referred to RRAM cells) can store information based on changes in electric resistance. In general, an RRAM cell includes a bottom electrode, a resistive switching layer, and a top electrode sequentially stacked. The resistance of the resistive switching layer varies according to an applied voltage. An RRAM cell can be configured in a plurality of resistance states. Each different resistance state may represent the logic value of a corresponding data bit. The resistance state can be configured by applying a programming voltage or current between the electrodes. For example, the RRAM cell can be coupled between a first access line (e.g., a bit line) and a second access line (e.g., a source line). The programming voltage may be applied on the bit line, with the source line coupled to ground. With an array having the increasing number of RRAM cells, the number of RRAM cells coupled between each pair of bit line and source line increases accordingly. This generally causes the bit lines and source lines each to extend with a substantially length.

In accordance with the ever increasing scaling trend toward the next advanced technology nodes, metal tracks configured as the bit lines and source lines tend to form narrower and/or form with tighter spacings. The existing RRAM devices commonly have its source lines and bit lines each formed as a single metal track. For example, the source line and the bit line, coupled to multiple RRAM cells, may be formed as a first metal track in a first metallization layer and a second metal track in a second metallization layer, respectively. The narrower metal track for each of the source/bit lines generally lead to higher electrical resistance. With the extensive length of the source/bit lines (e.g., to accommodate more RRAM cells), a relatively large IR drop can be present on the source/bit lines, which disadvantageously narrows a read window of the existing RRAM devices. Further, the large IR drop present on the source/bit lines in turn requires a larger programming voltage to successfully program the RRAM devices, which negatively impacts reliability and/or lifetime of the RRAM devices. Thus, the existing RRAM devices have not been entirely satisfactory in certain aspects.

The present disclosure provides various embodiments of a memory device (or circuit) that includes a memory array with a plural number of bit cells (e.g., RRAM cells), in which the bit cells are arranged over a number of rows and a number of columns. Each row can include a corresponding access line (e.g., a word line), and each column can include a corresponding pair of access lines (e.g., a source line and a bit line). In some embodiments, the source line and the bit line can each include multiple metal tracks disposed in respective one of metallization layers formed over a semiconductor substrate. These metallization layers (e.g., M0, M1, M2, M3, M4, M5, M6, M7, M8, etc.) are vertically stacked on top of one another. Each of the metallization layers includes a number of metal tracks embedded in one or more respective dielectric layers (sometimes referred to as inter-metal dielectrics), and the metal tracks in these metallization layers are hereby referred to as M0 tracks, M1 tracks, M2 tracks, M3 tracks, M4 tracks, M5 tracks, M6 tracks, M7 tracks, M8 tracks, etc.

For example, the source line can include a first metal track (e.g., an M0 track) and a second metal track (e.g., an M8 track), and the bit line can include a third metal track (e.g., an M2 track) and a fourth metal track (e.g., an M6 track). Further, the M0 track and M8 track, operatively forming the source line, can be coupled to each other through a number of first via structures, and the M2 track and M6 track, operatively forming the bit line, can be coupled to each other through a number of second via structures. The first via structures and the second via structures can be formed in a first strap region and a second strap region, respectively. Such a strap region is herein referred to as an auxiliary region on the substrate arranged next to a major region on the substrate where the bit cells are formed. The strap region may be formed along one of the edged of the major region. As such, the outmost bit cells can have a similar environment as the inner bit cells, thereby creating a more uniform operation of the bit cells regardless of its position in the memory array. By operatively forming the bit/source line with the different metal tracks, the corresponding electrical resistance of the bit/source line can be significantly suppressed. Further, by forming those via structures (to electrically connect corresponding different metal tracks) in the strap regions, no area penalty will be incurred. In some other embodiments, the word line can be formed in similar fashion, e.g., formed with multiple metal tracks that are disposed in respectively different metallization layers and are connected with via structures disposed in a strap region.

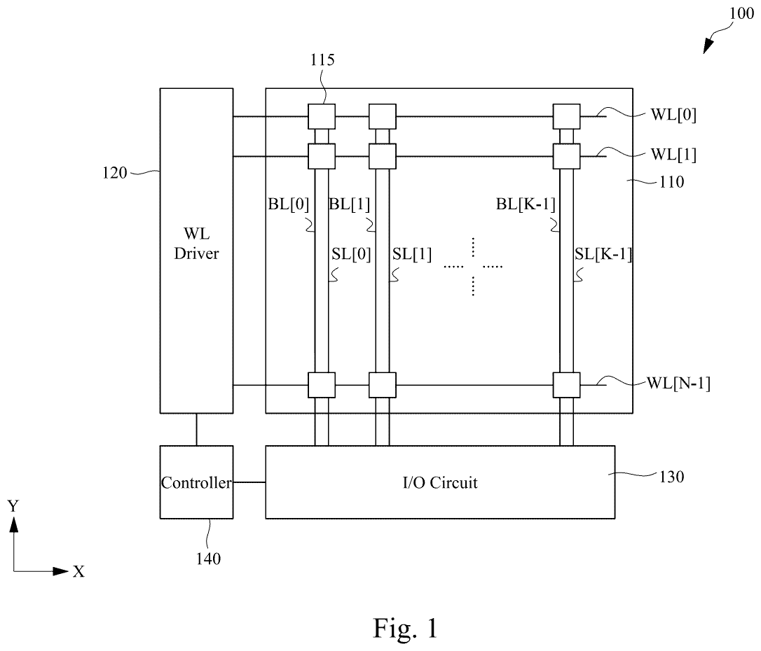

FIG. 1 illustrates an example block diagram of a memory circuit (or device) 100, in accordance with various embodiments of the present disclosure. As shown, the memory circuit 100 includes one or more memory arrays 110, a word line (WL) driver 120, and an input/output (I/O) circuit 130, and a memory controller 140. It should be appreciated that the block diagram of FIG. 1 has been simplified for illustrative purposes, and thus, the memory circuit 100 can include any of various other components, e.g., a sinker circuit, a source line (SL) driver, a pre-charge circuit, etc., while remaining within the scope of the present disclosure, in accordance with some embodiments of the present disclosure.

The memory array 110 includes a plurality of storage circuits or memory cells 115, which may be arranged in two-dimensional or three-dimensional arrays. In some embodiments, each of the memory cells 115 includes an RRAM cell configured to store a data bit corresponding to either a high resistance state (high resistance) or a low resistance state (low resistance). However, each of the memory cells 115 can include any of various other configuration of memory cells, while remaining within the scope of the present disclosure. For example, each of the memory cells 115 can include an MRAM cell, a spintronic memory cell, an OTP memory cell, or an SRAM cell.

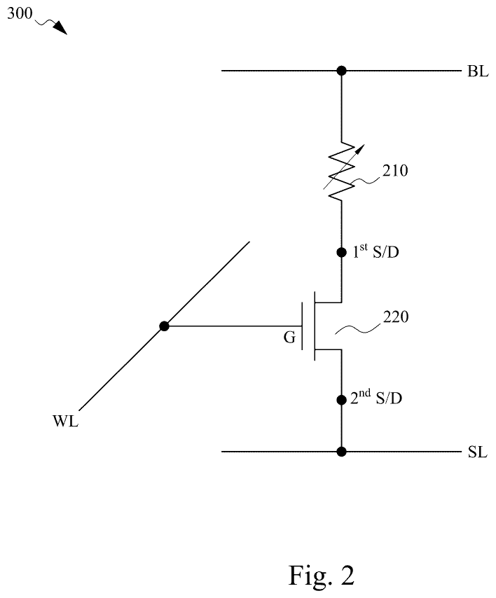

As will be shown below in FIG. 2, each of the memory (RRAM) cells 115 can be implemented as a 1-transistor-1-resistor (1T1R) structure, e.g., a resistor with variable resistance serially connected to a transistor. Each of the memory cells 115 of the memory array 110 may be coupled to a corresponding word line WL, a corresponding bit line BL, and a corresponding source line SL. For example, each of the memory cells 115 is disposed at the interaction of a corresponding word line WL and the combination of a corresponding bit line BL and a corresponding source line SL. As shown in the illustrative example of FIG. 1, the memory array 110 includes a number of word lines WLs, e.g., WL[0], WL[1] . . . . WL[N−1] disposed across multiple array rows, respectively. The number “N” can be any integer. Each of the word lines WLs can extend in a first direction (e.g., the X-axis). The memory array 110 further includes a number of bit lines BLs, e.g., BL[0], BL[1] . . . . BL[K−1], and a number of source lines SLs, e.g., SL[0], SL[0] . . . . SL[K−1], disposed across multiple array columns, respectively. The number “K” can be any integer. Each of the bit lines BLs and the source lines SLs can extend in a second direction (e.g., the Y-axis) perpendicular to the first direction.

The memory controller 140 is a hardware component that can control (e.g., read) operations of the memory array 110 through the WL controller 120 and/or the I/O circuit 130. The WL driver circuit 120 and the I/O circuit 130 may each be embodied as one or more logic circuits, one or more analog circuits, or a combination of them. In some embodiments, the WL driver circuit 120 can include a circuit configured to provide a voltage or current (e.g., a WL assertion signal with one or more pulses) through an asserted one of the word lines WLs of the memory array 110. The I/O circuit 130 can include a circuit configured to provide or sense a voltage or current through one or more of the bit lines BLs. Further, the I/O circuit 130 can include a circuit configured as a current source coupled to the memory array 110 through the source lines SLs. In some other embodiments, the memory circuit 100 can include more, fewer, or different components than shown in FIG. 1. For example, the memory circuit 100 can further include a timing controller that can provide control signals or clock signals to synchronize operations of the WL driver circuit 120 and the I/O circuit 130.

FIG. 2 illustrates an example circuit diagram of the memory cell 115 of FIG. 1, in accordance with some embodiments of the present disclosure. In FIG. 2, the memory cell 115 includes a selector transistor and a variable resistor connected in series (1T1R), in some embodiments. It, however, should be appreciated that the circuit diagram of FIG. 2 is provided merely for illustrative purpose, and does not intend to limit the scope of the present disclosure.

As shown, the memory cell 115 includes a variable resistor 210 and a selector transistor 220 that are connected in series. The variable resistor 210 can present a resistance state that is switchable or programmable between a low resistance state (LRS) and a high resistance state (HRS). The resistance state can be indicative of a data value (e.g., logic “1” or logic “0”) stored by the memory cell 115. Programming the memory cell 115 into the HRS (e.g., logic 0) is sometimes referred to as performing a RESET operation, and programming the memory cell 115 into the LRS (e.g., logic 1) is sometimes referred to as performing a SET operation.

Further, a first terminal of the variable resistor 210 is connected to a bit line BL, a second terminal of the variable resistor 210 is connected to a first source/drain terminal of the selector transistor 220, a gate terminal of the selector transistor 220 is connected to a word line WL, and a second source/drain terminal of the selector transistor 220 is connected to a source line SL which is typically connected to ground. With this configuration, the selector transistor 220 can be activated (e.g., turned on) by asserting the word line WL such as, for example, applying a signal with logic 1 on the gate terminal of the selector transistor 220. Upen being activated, another signal can be applied on the bit line BL to read or write the variable resistor 210.

In some embodiments, the selector transistor 220 can be formed in the front-end-of-line (FEOL) network, while the variable resistor 210 may be formed in the back-end-of-line (BEOL) network. In some other embodiments, both of the selector transistor 220 and the variable resistor 210 can be formed in the back-end-of-line (BEOL) network. Generally, the FEOL network refers to structures formed along the major surface of a semiconductor substrate, and the BEOL network refers to structures formed in metallization layers disposed over the major surface of the semiconductor substrate.

The variable resistor 210 typically includes a resistive switching element/variable resistive dielectric layer sandwiched between a top electrode and a bottom electrode. In some embodiments, the top electrode comprises titanium (Ti) and tantalum nitride (TaN), the bottom electrode comprises titanium nitride (TiN), and the variable resistive dielectric layer comprises nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), or copper oxide (CuO), for example. In some embodiments, the bottom electrode can be formed in a lower one of the metallization layers, and the top electrode can be formed in a higher one of the metallization layers. Further, a top electrode via (TEVA) can be formed over the top electrode, and a bottom electrode via (BEVA) can be formed below the bottom electrode, allowing the variable resistor 210 to connect to other structures/components such as, the selector transistor 220, the bit line BL, etc.

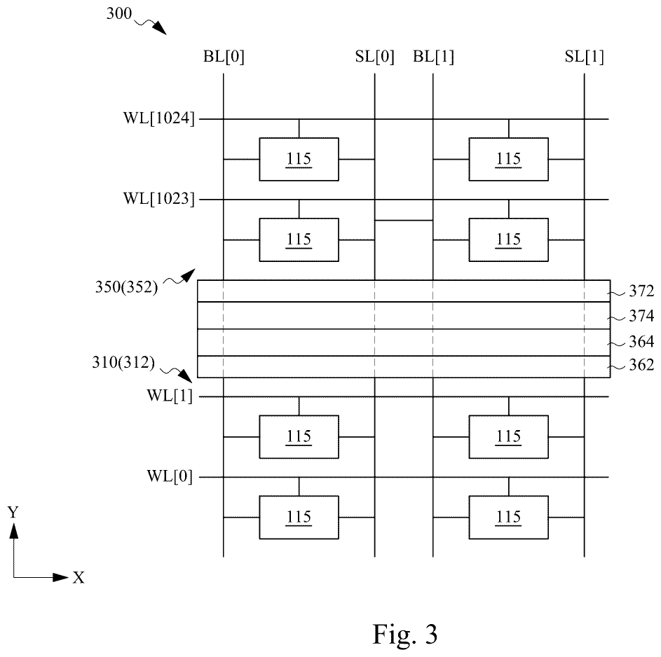

FIG. 3 illustrates an example schematic diagram of a portion of a memory circuit 300 configured based on the block diagram of the memory circuit 100 shown in FIG. 1, in accordance with some embodiments. It should be understood that the schematic diagram of FIG. 3 is provided for illustrative purposes, and does not intend to limit the scope of the present disclosure. Accordingly, the memory circuit 300 can include any of various other suitable components, while remaining within the scope of the present disclosure.

As shown, the memory circuit 300 includes two portions of a memory array, or two memory arrays, hereinafter memory array 310 and memory array 350, respectively. Each of the memory arrays 310 and 350 can include a plural number of memory cells (e.g., 115) arranged across a certain number of columns and a certain number of rows, where each column includes a respective bit line BL and a respective source line SL, and each row includes a respective word line WL.

For example, in FIG. 3, the memory array 310 includes two columns, one of which includes a bit line BL[0] and a source line SL[0] and the other of which includes a bit line BL[1] and a source line SL[1], and two rows, one of which includes a word line WL[0] and the other of which includes a word line WL[1]. Similarly, the memory array 350 includes two columns, one of which includes the bit line BL[0] and the source line SL[0] and the other of which includes the bit line BL[1] and the source line SL[1], and two rows, one of which includes a word line WL[1023] and the other of which includes a word line WL[1024]. Stated another way, the memory arrays 310 and 350 may share the same bit lines BLs and source lines SLs. Although two columns and two rows are shown in each of the memory arrays 310 and 350, it should be understood that each of the memory arrays 310 and 350 can include any number of columns and any number of rows while remaining within the scope of the present disclosure.

In some embodiments, the memory array 310 and the memory array 350, or their respective memory cells 115, can be physically formed in a first region 312 and in a second region 352 of a substrate, respectively. For example, the select transistors 220 of the memory cells 115 belonging to the memory array 310 can be formed along a major surface of the substrate in the first region 312 and the variable resistors 210 of the memory cells 115 belonging to the memory array 310 can be formed among a plurality of first metallization layers vertically disposed over the first region 312; and the select transistors 220 of the memory cells 115 belonging to the memory array 350 can be formed along the major surface of the substrate in the second region 352 and the variable resistors 210 of the memory cells 115 belonging to the memory array 350 can be formed among a plurality of second metallization layers vertically disposed over the second region 352. The first region 312 and the second region 352 can be physically arranged next to each other along a lengthwise direction of the bit lines BLs and source lines SLs (e.g., the Y-axis) shared by the memory arrays 310 and 350.

Further, interposed between the first region 312 and the second region 352 (e.g., along the Y-axis), a number of strap regions, 362, 364, 372, and 374, can be arranged. In accordance with some embodiments, these strap regions 362 to 374 can be configured to form respective via structures connecting the metal tracks disposed in different metallization layers, that are configured to operatively form the bit lines BLs and source lines SLs of the memory circuit 300. Such strap regions 362 to 374 are sometimes collectively referred to as being “stitched” to one or more of the memory arrays 310 and 350. In some embodiments, each of the strap regions 362 to 374 can extend along one edge of the memory arrays 310 and 350 (e.g., along the X-axis) to provide real estate for a respective number of via structures connecting the different metal tracks of each source line SL or bit line BL.

For example, the strap region 362 can be configured for a number of first via structures connecting different metal tracks of each bit line BL of the memory array 310 to be formed thereon, and the strap region 364 can be configured for a number of second via structures connecting different metal tracks of each source line SL of the memory array 310 to be formed thereon. Similarly, the strap region 372 can be configured for a number of third via structures connecting different metal tracks of each bit line BL of the memory array 350 to be formed thereon, and the strap region 374 can be configured for a number of fourth via structures connecting different metal tracks of each source line SL of the memory array 350 to be formed thereon. The strap regions 362 and 372 may sometimes be each referred to as a BL strap, and the strap regions 364 and 374 may sometimes be each referred to as an SL strap.

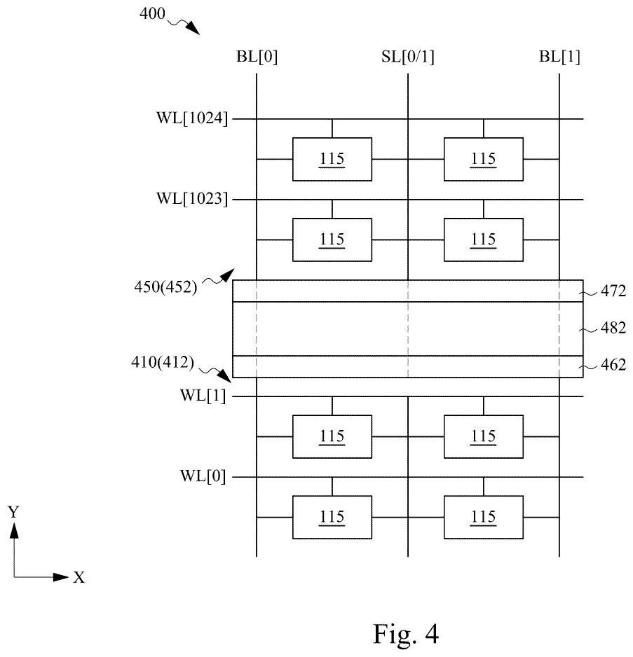

FIG. 4 illustrates an example schematic diagram of a portion of another memory circuit 400 configured based on the block diagram of the memory circuit 100 shown in FIG. 1, in accordance with some embodiments. It should be understood that the schematic diagram of FIG. 4 is provided for illustrative purposes, and does not intend to limit the scope of the present disclosure. Accordingly, the memory circuit 400 can include any of various other suitable components, while remaining within the scope of the present disclosure.

Similar to the memory circuit 300 (FIG. 3), the memory circuit 400 includes two portions of a memory array, or two memory arrays, hereinafter memory array 410 and memory array 450, respectively. Each of the memory arrays 410 and 450 can include a plural number of memory cells (e.g., 115) arranged across a certain number of columns and a certain number of rows, where each column includes a respective bit line BL and each row includes a respective word line WL. Different from the memory circuit 300 (FIG. 3), two or more columns of the memory circuit 400 may share a common source line SL.

For example, in FIG. 4, the memory array 410 includes two columns, one of which includes a bit line BL[0] and the other of which includes a bit line BL[1], and two rows, one of which includes a word line WL[0] and the other of which includes a word line WL[1], where these two columns share a common source line SL[0/1]. Similarly, the memory array 450 includes two columns, one of which includes the bit line BL[0] and the other of which includes the bit line BL[1], and two rows, one of which includes the word line WL[1023] and the other of which includes the word line WL[1024], where these two columns share the common source line SL[0/1]. Stated another way, the memory arrays 410 and 450 may share the same bit lines BLs and source lines SLs. Although two columns and two rows are shown in each of the memory arrays 410 and 450, it should be understood that each of the memory arrays 410 and 450 can include any number of columns and any number of rows while remaining within the scope of the present disclosure.

Similar to the memory circuit 300, a number of strap region 462, 472, and 482 can be interposed between a first region 412 and a second region 452 (e.g., along the Y-axis), where the memory arrays 410 and 450 are respectively formed. The strap region 462 can be configured for a number of first via structures connecting different metal tracks of each bit line BL to be formed thereon, the strap region 472 can be configured for a number of second via structures connecting different metal tracks of each bit line BL to be formed thereon, and the strap region 482 can be configured for a number of third via structures connecting different metal tracks of each common source line SL to be formed thereon.

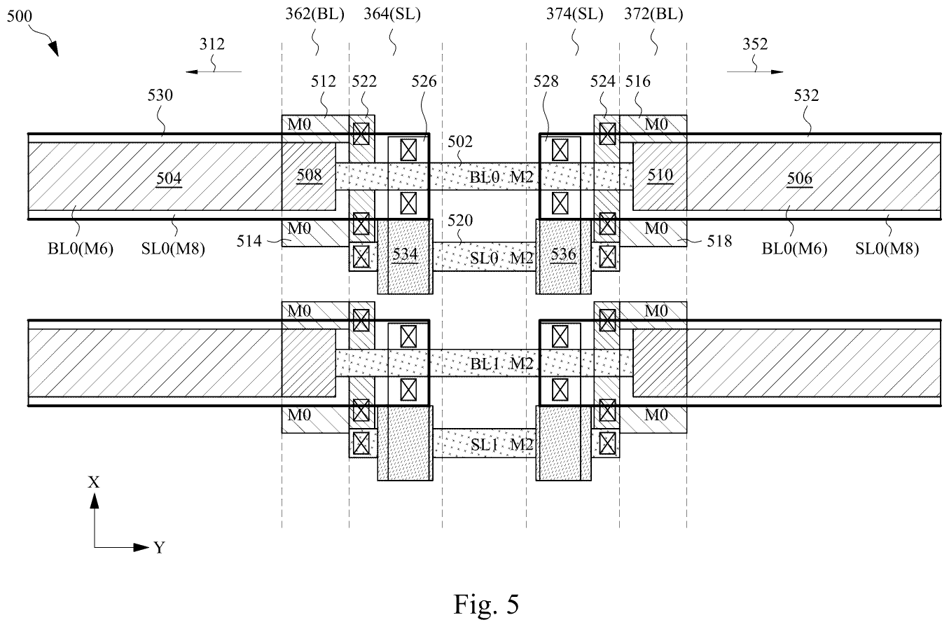

FIG. 5 illustrates an example layout 500 configured to form the bit lines BL[0] and BL[1] and the source lines SL[0] and SL[1] of the memory circuit 300, in accordance with some embodiments. Accordingly, some of the reference numerals of FIG. 3 will be used again in the following discussion of the layout 500 for reference purposes. In accordance with some embodiments of the present disclosure, each of the bit lines BL[0] and BL[1] and the source lines SL[0] and SL[1] can be formed as multiple metal tracks in respectively different metallization layers, and these metal tracks can be coupled to each other through a respective number of via structures. The bit line BL[0] and source line SL[0] will be selected as a representative example in the following discussion.

For example, the bit line BL[0] can be formed based on an M2 track 502, an M6 track 504, an M6 track 506, a number of via structures 508, and a number of via structures 510; and the source line SL[0] can be formed based on M0 tracks 512, 514, 516, and 518, an M2 track 520, M1 track 522 and 524, M7 tracks 526 and 528, and M8 tracks 530 and 532, a number of via structures 534, and a number of via structures 536. In some embodiments, the M0 tracks 512 to 518, M2 tracks 502 and 520, M6 tracks 504-506, and M8 tracks 530-532 can extend along the Y-axis, while the M1 tracks 522-524 and the M7 tracks 526-528 can extend along the X-axis. As mentioned above, metallization layers M0, M1, M2, M3, M4, M5, M6, M7, M8, etc., (with their respective metal tracks) are vertically arranged in this order from the major surface of a substrate to a topmost one of the metallization layers (e.g., M10).

The via structures 508, configured to electrically couple the M2 track 502 to the M6 track 504, can be disposed in the (BL) strap region 362; and the via structures 510, configured to electrically couple the M2 track 502 to the M6 track 506, can be disposed in the (BL) strap region 372. As such, the bit line BL[0] can be formed by the M2 track 502, the via structures 508, the via structures 510, the M6 track 504, and the M6 track 506. The via structures 508 can electrically couple the M2 track 502 to the M6 track 504, and the via structures 510 can electrically couple the M2 track 502 to the M6 track 506. In some embodiments, the via structures 508 can include a number of via structures interposed between the metallization layers M2 and M3 (sometimes referred to as V2s), between the metallization layers M3 and M4 (sometimes referred to as V3s), between the metallization layers M4 and M5 (sometimes referred to as V4s), and between the metallization layers M5 and M6 (sometimes referred to as V5s), respectively. Similarly, the via structures 510 can include a number of via structures interposed between the metallization layers M2 and M3 (e.g., V2s), between the metallization layers M3 and M4 (e.g., V3s), between the metallization layers M4 and M5 (e.g., V4s), and between the metallization layers M5 and M6 (e.g., V5s), respectively.

The via structures 534, configured to electrically couple the M2 track 520 to the M8 track 530, can be disposed in the (SL) strap region 364; and the via structures 536, configured to electrically couple the M2 track 520 to the M8 track 532, can be disposed in the (SL) strap region 374. Further, the M2 track 520 can be coupled to the underlying M0 tracks 512-514 through at least the M1 track 522, and to the underlying M0 tracks 516-518 through at least the M1 track 524. The M8 track 530 can be coupled to the underlying M7 track 526, and the M8 track 532 can be coupled to the underlying M7 track 528. As such, the source line SL[0] can be formed by the M0 tracks 512-518, the M1 tracks 522-524, the via structures 534, the via structures 536, the M7 tracks 526-528, and the M8 tracks 530-532. The via structures 534 can electrically couple the M2 track 520 to the M8 track 530, and the via structures 536 can electrically couple the M2 track 520 to the M8 track 532.

In some embodiments, the via structures 534 can include a number of via structures interposed between the metallization layers M2 and M3 (e.g., V2s), between the metallization layers M3 and M4 (e.g., V3s), between the metallization layers M4 and M5 (e.g., V4s), between the metallization layers M5 and M6 (e.g., V5s), and between the metallization layers M6 and M7 (e.g., V6s), respectively. Similarly, the via structures 536 can include a number of via structures interposed between the metallization layers M2 and M3 (e.g., V2s), between the metallization layers M3 and M4 (e.g., V3s), between the metallization layers M4 and M5 (e.g., V4s), between the metallization layers M5 and M6 (e.g., V5s), and between the metallization layers M6 and M7 (e.g., V6s), respectively.

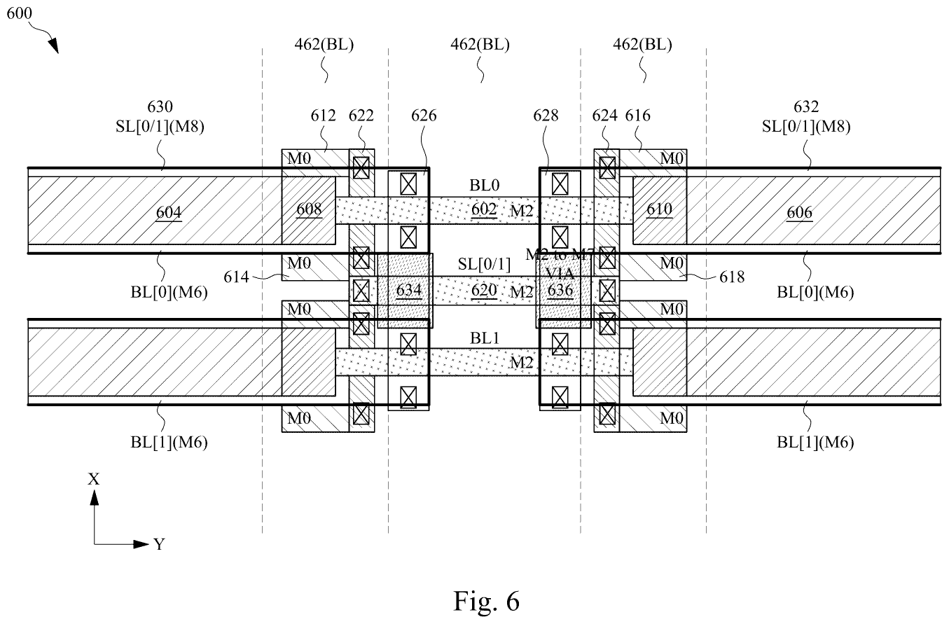

FIG. 6 illustrates an example layout 600 configured to form the bit lines BL[0] and BL[1] and the common source line SL[0/1] of the memory circuit 400, in accordance with some embodiments. Accordingly, some of the reference numerals of FIG. 4 will be used again in the following discussion of the layout 600. In accordance with some embodiments of the present disclosure, each of the bit lines BL[0] and BL[1] and the source line SL[0/1] can be formed as multiple metal tracks in respectively different metallization layers, and these metal tracks can be coupled to each other through a respective number of via structures. The bit line BL[0] and common source line SL[0/1] will be selected as a representative example in the following discussion.

For example, the bit line BL[0] can be formed based on an M2 track 602, an M6 track 604, an M6 track 606, a number of via structures 608, and a number of via structures 610; and the common source line SL[0/1] can be formed based on M0 tracks 612, 614, 616, and 618, an M2 track 620, M1 track 622 and 624, M7 tracks 626 and 628, and M8 tracks 630 and 632, a number of via structures 634, and a number of via structures 636. In some embodiments, the M0 tracks 612 to 618, M2 tracks 602 and 620, M6 tracks 604-606, and M8 tracks 630-632 can extend along the Y-axis, while the M1 tracks 622-624 and the M7 tracks 626-628 can extend along the X-axis. As mentioned above, metallization layers M0, M1, M2, M3, M4, M5, M6, M7, M8, etc., (with their respective metal tracks) are vertically arranged in this order from the major surface of a substrate to a topmost one of the metallization layers (e.g., M10).

The via structures 608, configured to electrically couple the M2 track 602 to the M6 track 604, can be disposed in the (BL) strap region 662; and the via structures 610, configured to electrically couple the M2 track 602 to the M6 track 606, can be disposed in the (BL) strap region 672. As such, the bit line BL[0] can be formed by the M2 track 602, the via structures 608, the via structures 610, the M6 track 604, and the M6 track 606. The via structures 608 can electrically couple the M2 track 602 to the M6 track 604, and the via structures 610 can electrically couple the M2 track 602 to the M6 track 606. In some embodiments, the via structures 608 can include a number of via structures interposed between the metallization layers M2 and M3 (sometimes referred to as V2s), between the metallization layers M3 and M4 (sometimes referred to as V3s), between the metallization layers M4 and M5 (sometimes referred to as V4s), and between the metallization layers M5 and M6 (sometimes referred to as V5s), respectively. Similarly, the via structures 610 can include a number of via structures interposed between the metallization layers M2 and M3 (e.g., V2s), between the metallization layers M3 and M4 (e.g., V3s), between the metallization layers M4 and M5 (e.g., V4s), and between the metallization layers M5 and M6 (e.g., V5s), respectively.

The via structures 634, configured to electrically couple the M2 track 620 to the M8 track 630, can be disposed in the (SL) strap region 482; and the via structures 636, configured to electrically couple the M2 track 620 to the M8 track 632, can be disposed in the (SL) strap region 482. Further, the M2 track 620 can be coupled to the underlying M0 tracks 612-614 through at least the M1 track 622, and to the underlying M0 tracks 616-618 through at least the M1 track 624. The M8 track 630 can be coupled to the underlying M7 track 626, and the M8 track 632 can be coupled to the underlying M7 track 628. As such, the common source line SL[0/1] can be formed by the M0 tracks 612-618, the M1 tracks 622-624, the via structures 634, the via structures 636, the M7 tracks 626-628, and the M8 tracks 630-632. The via structures 634 can electrically couple the M2 track 620 to the M8 track 630, and the via structures 636 can electrically couple the M2 track 620 to the M8 track 632.

In some embodiments, the via structures 634 can include a number of via structures interposed between the metallization layers M2 and M3 (e.g., V2s), between the metallization layers M3 and M4 (e.g., V3s), between the metallization layers M4 and M5 (e.g., V4s), between the metallization layers M5 and M6 (e.g., V5s), and between the metallization layers M6 and M7 (e.g., V6s), respectively. Similarly, the via structures 636 can include a number of via structures interposed between the metallization layers M2 and M3 (e.g., V2s), between the metallization layers M3 and M4 (e.g., V3s), between the metallization layers M4 and M5 (e.g., V4s), between the metallization layers M5 and M6 (e.g., V5s), and between the metallization layers M6 and M7 (e.g., V6s), respectively.

In the dedicated source line structure (e.g., the layout 500), each column has its own source line, e.g., the first column having the source line SL[0] and the second column having the source line SL[1]. The source line SL[0] is formed at least by the M0 tracks 512-518, M1 tracks 522-524, M2 track 520, M7 tracks 526-528, M8 tracks 530-532, and via structures 534-536; and the source line SL[1] can be formed at least by the combination of corresponding (different) M0 to M8 tracks, the discussion of which will not be repeated. By contrast, in the shared source line structure (e.g., the layout 600), two or more different columns can have one common source line, e.g., the first column and the second column having the source line SL[0/1] in common. The source line SL[0/1] is formed at least by the M0 tracks 612-618 (and other M0 tracks of the layout 600), M1 tracks 622-624, M2 track 620, M7 tracks 626-628, M8 tracks 630-632 (and other M8 tracks of the layout 600), and via structures 634-636. Stated another way, in the dedicated source line structure, each column can have its corresponding source line SL formed by one M2 track and one or more M8 tracks, while, in the shared source line structure, multiple column can share one corresponding source line SL formed by one M2 track and one or more M8 tracks.

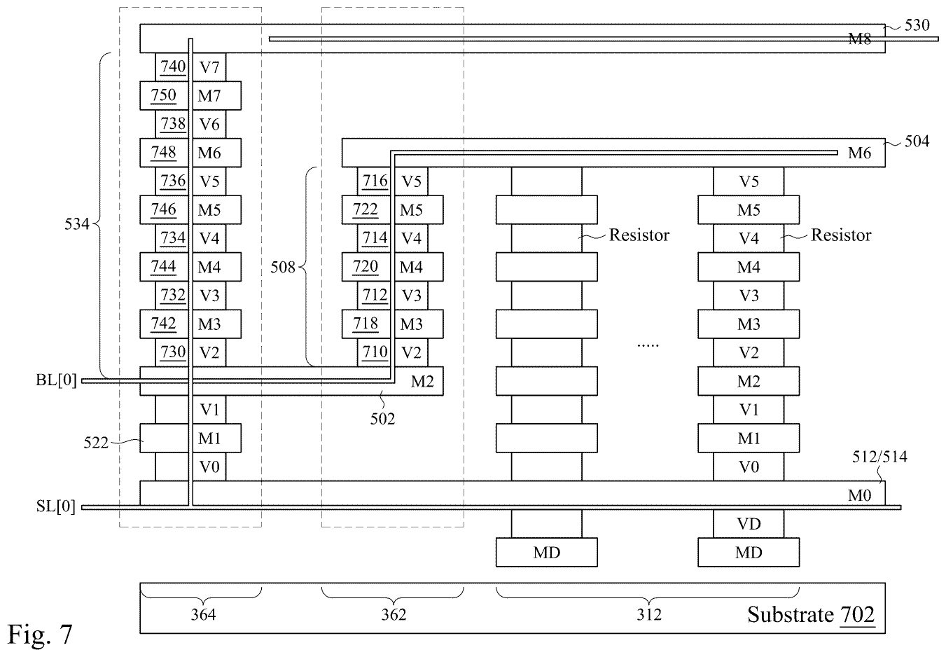

FIG. 7 illustrates a cross-sectional view of a portion of a semiconductor device formed based on one of the foregoing layouts (e.g., the layout 500 of FIG. 5), in accordance with some embodiments. It should be noted that the cross-sectional view shown in FIG. 7 combines (or overlaps) multiple cross-sectional views, each of which cuts along a line extending in the Y-axis (as indicated in FIG. 5). As such, the combined cross-sectional view of FIG. 7 may include the different metal tracks operatively forming each of the source line (e.g., SL[0]) and bit line (e.g., BL[0]).

For example, in FIG. 7, the bit line BL[0] includes the M2 track 502, the M6 track 504, and the via structures 508; and the source line SL[0] includes the M0 track 512 and/or 514, the M8 track 530, and the via structures 534. The via structures 508, arranged over the strap region 362 (e.g., of a substrate 702), can include V2 via structure 710, V3 via structure 712, V4 via structure 714, and V5 via structure 716, and M3 track 718, M4 track 720, and M5 track 722 that are alternately arranged with respect to the via structures 710 to 716. The via structures 534, arranged over the strap region 364 (e.g., of the substrate 702), can include V2 via structure 730, V3 via structure 732, V4 via structure 734, V5 via structure 736, V6 via structure 738, and V7 via structure 740, and M3 track 742, M4 track 744, M5 track 746, M6 track 748, and M7 track 750 that are alternately arranged with respect to the via structures 730 to 740.

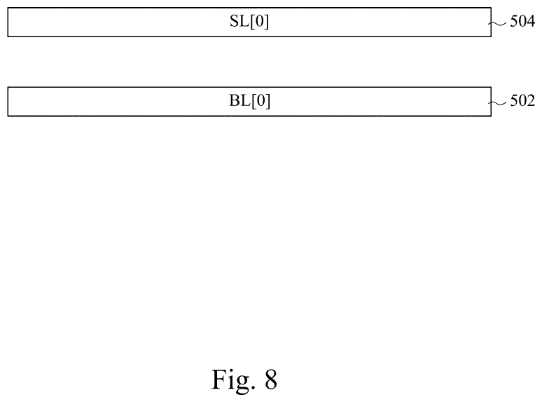

The M6 track 504 can be coupled to the M2 track 502 through the via structures 508, operatively forming the bit line BL[0]; and the M8 track 530 can be coupled to the M0 track 512/514 through the via structures 534 (and the underlying via structure V1, M1 track 522, and via structure V0), operatively forming the source line SL[0]. It should be noted that, interposed between the V2 via structure 730 and the via structure V1, another M2 track is present (but not viable in FIG. 7). This M2 track (e.g., 762), forming a part of the source line SL[0], and the M2 track 502, forming a part of the bit line BL[0] are arranged in parallel with each other, as shown in the top view of FIG. 8. As such, the M2 track 762 is not configure to electrically connect to the via structures 508.

Disposed next to the strap region 362, the region 312 (e.g., of the substrate 702), a plurality of memory cells (e.g., 115) can be formed, wherein each of the memory cells can include a selector transistor and a variable resistor coupled to each other in series. The selector transistors can be formed in the region 312 along a major surface of the substrate 702, and the variable resistors can be formed in the region 312, e.g., between the metallization layers M4 and M5. In some embodiments, one source/drain terminal of each of the selector transistors is coupled to its corresponding variable resistor (formed thereupon) through at least one contact structure MD and one via structure VD, while the other source/drain terminal of each of the selector transistors is coupled to the source line SL[0] or the M0 track 512/514.

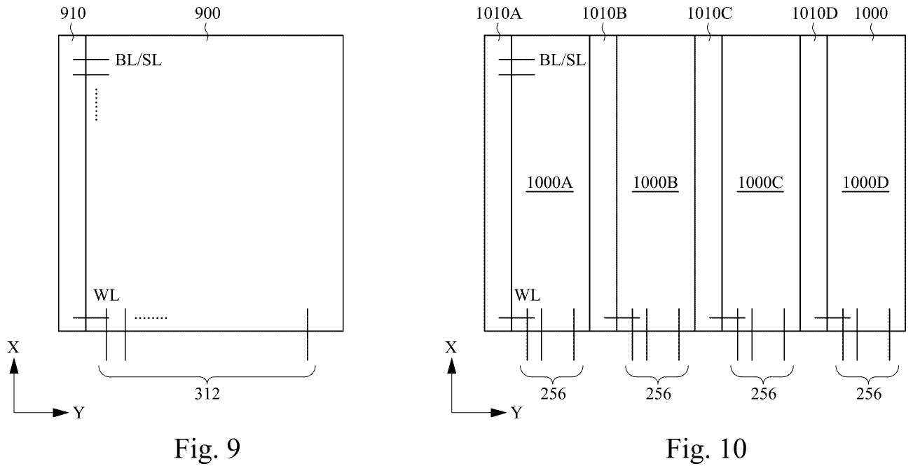

FIG. 9 and FIG. 10 are schematic diagrams respectively illustrating flexible arrangements of one or more strap regions and a memory array, in accordance with some embodiments. The strap regions, similar to the above-discussed strap region, are each configured for forming a number of via structures arranged across multiple metallization layers. These via structures can electrically connect the metal tracks that are disposed in different metallization layers and operatively form a source line SL or a bit line BL. It should be understood that, in FIGS. 9-10, the relative orientation among the strap regions and the memory array is provided merely provided for illustrative purposes and does not intend to limit the scope of the present disclosure.

For example, in FIG. 9, a memory array 900, including a plural number of memory cells arranged across a number (e.g., 1024) of word lines WLs extending in the X-axis and a number of source lines SLs and bit lines BLs extending in the Y-axis, can be stitched with a strap region 910. The strap region 910 can be configured for forming a number of first via structures coupling two or more first metal tracks to each other, and a number of second via structures coupling two or more second metal tracks to each other. The first metal tracks can operatively form a bit line BL, and the second metal tracks can operatively form a source line SL.

For another example, in FIG. 10, a memory array 1000, including a plural number of memory cells arranged across a number (e.g., 1024) of word lines WLs extending in the X-axis and a number of source lines SLs and bit lines BLs extending in the Y-axis, can be stitched with multiple strap regions. A first portion of the memory array 1000A (e.g., with 256 word lines WLs) is stitched with a first strap region 1010A, a second portion of the memory array 1000B (e.g., with 256 word lines WLs) is stitched with a second strap region 1010B, a third portion of the memory array 1000C (e.g., with 256 word lines WLs) is stitched with a third strap region 1010C, and a fourth portion of the memory array 1000D (e.g., with 256 word lines WLs) is stitched with a fourth strap region 1010D. The strap regions 1010A to 1010D can each be configured for forming a number of first via structures coupling two or more first metal tracks to each other, and a number of second via structures coupling two or more second metal tracks to each other. The first metal tracks can operatively form a bit line BL, and the second metal tracks can operatively form a source line SL.

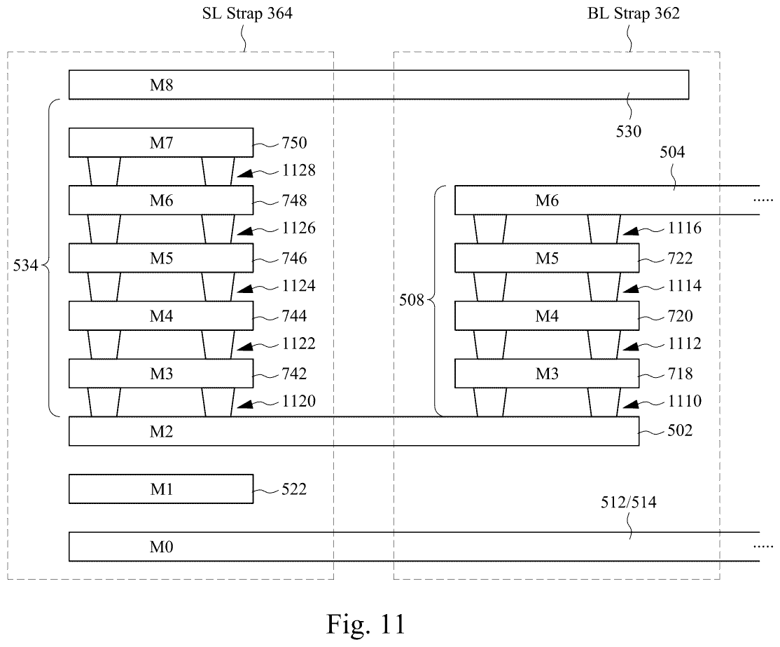

FIG. 11 illustrates a cross-sectional view of a portion of a semiconductor device formed based on one of the foregoing layouts (e.g., the layout 500 of FIG. 5), in accordance with some embodiments. The cross-sectional view of FIG. 11 is similar to the cross-sectional view of FIG. 7, except that, in FIG. 11, the via structures 508 and 534 each include multiple via structures connecting the vertically adjacent metal tracks. Such multiple via structures can further reduce a resistance of the corresponding access line.

For example, the via structures 508 include multiple via structures 1110 connecting the M2 track 502 to the M3 track 718, multiple via structures 1112 connecting the M3 track 718 to the M4 track 720, multiple via structures 1114 connecting the M4 track 720 to the M5 track 722, and multiple via structures 1116 connecting the M5 track 722 to the M6 track 504. Similarly, the via structures 534 include multiple via structures 1120 connecting the M2 track 762 (shown in FIG. 8) to the M3 track 742, multiple via structures 1122 connecting the M3 track 742 to the M4 track 744, multiple via structures 1124 connecting the M4 track 744 to the M5 track 746, multiple via structures 1126 connecting the M5 track 746 to the M6 track 748, and multiple via structures 1128 connecting the M6 track 748 to the M7 track 750.

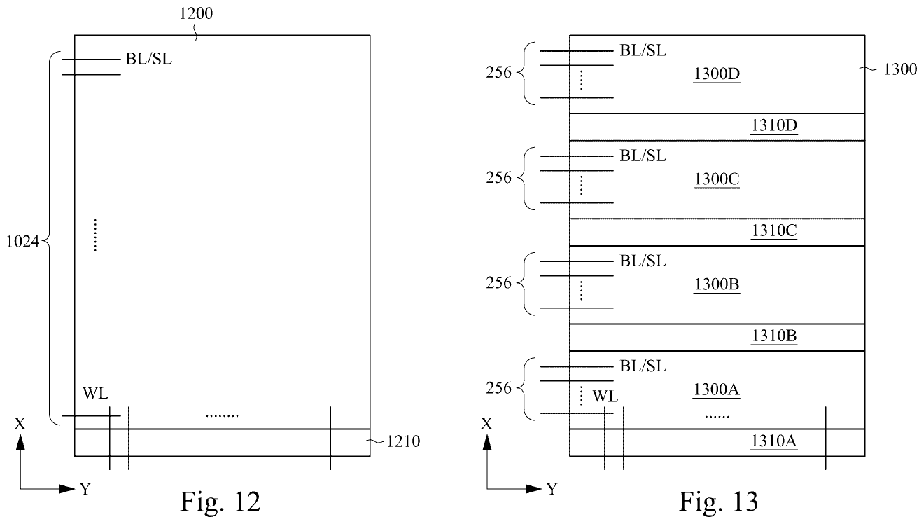

FIG. 12 and FIG. 13 are schematic diagrams respectively illustrating flexible arrangements of one or more strap regions and a memory array, in accordance with some embodiments. The strap regions, similar to the above-discussed strap region, are each configured for forming a number of via structures arranged across multiple metallization layers. These via structures can electrically connect the metal tracks that are disposed in different metallization layers except that and operatively form a word line WL. It should be understood that, in FIGS. 12-13, the relative orientation among the strap regions and the memory array is provided merely provided for illustrative purposes and does not intend to limit the scope of the present disclosure.

For example, in FIG. 12, a memory array 1200, including a plural number of memory cells arranged across a number of word lines WLs extending in the X-axis and a number (e.g., 1024) of source lines SLs and a number of (e.g., 1024) bit lines BLs extending in the Y-axis, can be stitched with a strap region 1210. The strap region 1210 can be configured for forming a number of via structures coupling two or more metal tracks to each other. The metal tracks can operatively form a word line WL.

For another example, in FIG. 13, a memory array 1300, including a plural number of memory cells arranged across a number of word lines WLs extending in the X-axis and a number (e.g., 1024) of source lines SLs and a number (e.g., 1024) of bit lines BLs extending in the Y-axis, can be stitched with multiple strap regions. A first portion of the memory array 1300A (e.g., with 256 source/bit lines SLs/BLs) is stitched with a first strap region 1310A, a second portion of the memory array 1300B (e.g., with 256 source/bit lines SLs/BLs) is stitched with a second strap region 1310B, a third portion of the memory array 1300C (e.g., with 256 source/bit lines SLs/BLs) is stitched with a third strap region 1310C, and a fourth portion of the memory array 1300D (e.g., with 256 source/bit lines SLs/BLs) is stitched with a fourth strap region 1310D. The strap regions 1310A to 1310D can each be configured for forming a number of via structures coupling two or more metal tracks to each other. The metal tracks can operatively form a word line WL.

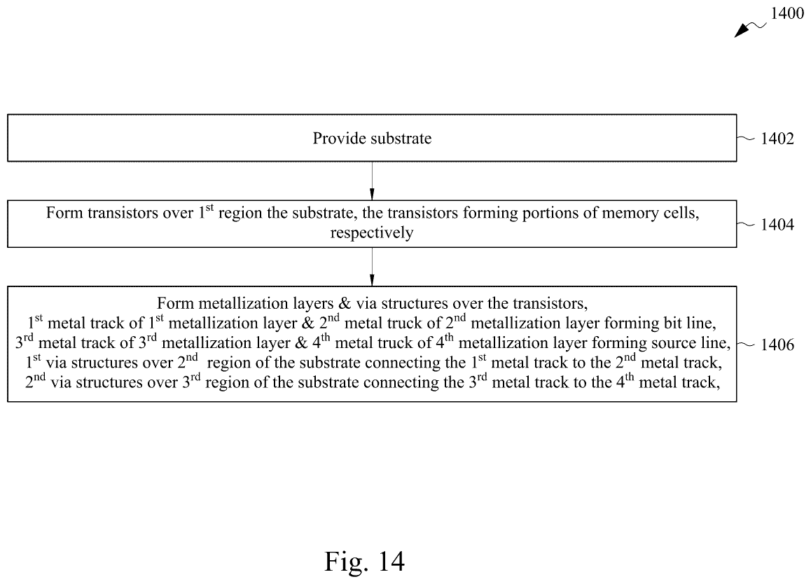

FIG. 14 illustrates a flowchart of an example method 1400 for forming a memory device, in accordance with some embodiments. The following discussion of the method 1400 may sometimes be referred to the above-described figures. It is noted that the method 1400 is merely an example and is not intended to limit the present disclosure. Accordingly, it is understood that additional operations may be provided before, during, and after the method 1400 of FIG. 14, and that some other operations may only be briefly described herein.

In some embodiments, at least some of the operations described in the method 1400 may be used to form a memory device that includes a number of access lines (e.g., source lines SLs, bit lines BLs) configured based on the forgoing layouts or schematic diagrams. For example, the memory device, formed by the method 1400, can have its access line constituted by at least two metal tracks that are disposed in respectively different metallization layers and coupled to each other through a number of via structures stitched in a respective strap region.

The method 1400 starts with operation 1402 in which a substrate is provided. The substrate includes a semiconductor material substrate, for example, silicon. Alternatively, the substrate may include other elementary semiconductor material such as, for example, germanium. The substrate may also include a compound semiconductor such as silicon carbide, gallium arsenic, indium arsenide, and indium phosphide. The substrate may include an alloy semiconductor such as silicon germanium, silicon germanium carbide, gallium arsenic phosphide, and gallium indium phosphide. In one embodiment, the substrate includes an epitaxial layer. For example, the substrate may have an epitaxial layer overlying a bulk semiconductor. Furthermore, the substrate may include a semiconductor-on-insulator (SOI) structure. For example, the substrate may include a buried oxide (BOX) layer formed by a process such as separation by implanted oxygen (SIMOX) or other suitable technique, such as wafer bonding and grinding.

The method 1400 proceeds to operation 1404 in which a plurality of transistors are formed over a first region of the substrate. In some embodiments, the plurality of transistors operatively form portions of a plurality of memory cells, respectively. For example, the transistors, which may be formed in any of various transistor structures (e.g., planar transistors, FinFETs, GAA transistors, etc.), can serve as the selector transistors of a number of memory cells, respectively. As will be discussed below, each of the memory cells can further include a variable resistor formed directly above. Each of these transistors can have its gate terminal electrically connected to a respective word line WL, a first source/drain terminal electrically connected to a respective source line SL, and a second source/drain terminal electrically connected to the respective variable resistor. These selector transistors (and their corresponding variable resistors) can be formed in the first region, e.g., 312 shown in FIG. 7.

The method 1400 proceeds to operation 1406 in which a plurality of metallization layers and a plurality of via structures are formed over the plurality of transistors. For example, metallization layers M0, M1, M2, M3, M4, M5, M6, M7, M8, and so on can be formed over the substrate in such an order. Each of these metallization layers (e.g., M0 . . . M8) includes at least one metal track, and the metal track in adjacent ones of the metallization layers are electrically coupled to each other through at least a corresponding one of the via structures.

In some embodiments, a first one of the metallization layers includes a first metal track, a second one of the metallization layers includes a second metal track, a third one of the metallization layers includes a third metal track, and a fourth one of the metallization layers a fourth metal track. The first metal track and the second metal track are electrically connected to each other, which can collectively serve as a first access line (e.g., a bit line BL) for the plurality of memory cells; and the third metal track and the fourth metal track are electrically connected to each other, which can collectively serve as a second access line (e.g., a source line SL) for the plurality of memory cells. The first to fourth metallization layers can be different from one another.

In some embodiments, the fourth metallization layer may be disposed above the second metallization layer, the second metallization layer may be disposed above the first metallization layer, and the first metallization layer may be disposed above the third metallization layer. Further, in some embodiments, the first to fourth metal tracks may extend along the same direction. For example, the M2 track 502 (a non-limiting implementation of the first metal track) and the M6 track 504 (a non-limiting implementation of the second metal track), disposed in the M2 layer and the M6 layer, respectively, can operatively form at least a portion of the bit line BL[0]; and the M0 track 512/514 (a non-limiting implementation of the third metal track) and the M8 track 530 (a non-limiting implementation of the fourth metal track), disposed in the M0 layer and the M8 layer, respectively, can operatively form at least a portion of the source line SL[0].

In addition to the metal tracks, a number of first via structures and a number of second via structures can be formed in operation 1406. The first via structure can connect the first metal track to the second metal track, and the second via structure can connect the third metal track to the fourth metal track. As such, the first metal track and the second metal track of the bit line BL can be electrically connected to each other, and the third metal track and the fourth metal track of the source line SL can be electrically connected to each other. In some embodiments, the first via structures and second via structures can be formed in a first strap region and a second strap region, respectively. The first strap region and the second strap region can be stitched to the main (first) region where the memory cells are formed. For example, the first via structures (e.g., 508) can be formed in a second region of the substrate or a first strap region, e.g., 362 shown in FIG. 7; and the second via structures (e.g., 534) can formed in a third second region of the substrate or a second strap region, e.g., 364 shown in FIG. 7.

The metal tracks and the via structures can be formed by a single or dual damascene process. Generally, through the single damascene process, a metal track and a corresponding via structure may be separately formed; and through the dual damascene process, a metal track and a corresponding via structure may be concurrently formed. As a representative example, the dual damascene process may start with deposition of a via stop layer over a first metal track embedded in a first dielectric layer, or a first inter metal dielectric (IMD). The via stop layer is an etch stop layer, which is subject to a photolithographic process using a photoresist and anisotropic etching steps. A via dielectric layer is formed over the via stop layer. Where the via dielectric layer is of an oxide material, such as silicon oxide, the via stop layer is a nitride, such as silicon nitride, so the two layers can be selectively etched. The via dielectric layer is then subject to a further photolithographic process using a photoresist and etching steps to form the pattern of the via structures. A second dielectric layer, or a second IMD, is formed over the via dielectric layer. Where the second dielectric layer is of an oxide material, such as silicon oxide, the via stop layer is a nitride, such as silicon nitride, so the two layers can be selectively etched. The second dielectric layer and the via dielectric layer are then subject to a further photolithographic process and etching steps to simultaneously form one or more openings exposing the first metal track. The openings are then filled with a metal material (e.g., copper or copper alloy), forming a second metal track and a via structure connecting the first metal track to the second metal track.

In one aspect of the present disclosure, a memory device is disclosed. The memory device includes a plurality of memory cells, each of the plurality of memory cells including a resistive element and a transistor connected in series between a first access line and a second access line. The first access line includes at least a first metal track disposed in a first one of a plurality of metallization layers over a substrate, and a second metal track disposed in a second one of the plurality of metallization layers. The second access line includes at least a third metal track disposed in a third one of the plurality of metallization layers, and a fourth metal track disposed in a fourth one of the plurality of metallization layers. The second metallization layer is disposed over the fourth metallization layer, the fourth metallization layer is disposed over the third metallization layer, and the third metallization layer is disposed over the first metallization layer.

In another aspect of the present disclosure, a semiconductor device is disclosed. The semiconductor device includes a first memory array including a plurality of first memory cells arranged over a plurality of first columns and a plurality of first rows, wherein each of the plurality of first rows includes at least a first word line, and each of the plurality of first columns includes at least a first bit line and a first source line; a first strap region disposed next to the first memory array along a lateral direction; and a second strap region disposed next to the first strap region along the lateral direction. A plurality of first via structures are formed in the first strap region, and the plurality of first via structures are configured to electrically connect a first metal track and a second metal track operatively constituting at least a part of each of the first source lines. A plurality of second via structures are formed in the second strap region, and the plurality of first via structures are configured to electrically connect a third metal track and a fourth metal track operatively constituting at least a part of each of the first bit lines.

In yet another aspect of the present disclosure, a method for forming semiconductor devices is disclosed. The method includes forming a plurality of transistors over a first region of a substrate, wherein the plurality of transistors operatively form portions of a plurality of memory cells, respectively. The method includes forming a plurality of metallization layers over the plurality of transistors. A first one of the plurality of metallization layers includes a first metal track, a second one of the plurality of metallization layers includes a second metal track, a third one of the plurality of metallization layers includes a third metal track, and a fourth one of the plurality of metallization layers a fourth metal track. The first metal track and the second metal track are electrically connected to each other and collectively serve as a first access line for the plurality of memory cells, and the third metal track and the fourth metal track are electrically connected to each other and collectively serve as a second access line for the plurality of memory cells.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a plurality of memory cells, each of the plurality of memory cells including a resistive element and a transistor connected in series between a first access line and a second access line;
wherein the first access line includes at least:
a first metal track disposed in a first one of a plurality of metallization layers over a substrate; and
a second metal track disposed in a second one of the plurality of metallization layers;
wherein the second access line includes at least:
a third metal track disposed in a third one of the plurality of metallization layers; and
a fourth metal track disposed in a fourth one of the plurality of metallization layers; and
wherein the second metallization layer is disposed over the fourth metallization layer, the fourth metallization layer is disposed over the third metallization layer, and the third metallization layer is disposed over the first metallization layer.

2. The memory device of claim 1, wherein the resistive elements of the plurality of memory cells are disposed between a fifth one of the plurality of metallization layers and a sixth one of the plurality of metallization layers.

3. The memory device of claim 2, wherein the fifth metallization layer and the sixth metallization layer are arranged between the third metallization layer and the fourth metallization layer.

4. The memory device of claim 2, wherein the transistors of the plurality of memory cells are disposed along a major surface of the substrate, and located directly below the resistive elements.

5. The memory device of claim 1,
wherein the first access line further includes a plurality of first via structures electrically coupling the first metal track to the second metal track; and
wherein the second access line further includes a plurality of second via structures electrically coupling the third metal track to the fourth metal track.

6. The memory device of claim 5, wherein, when viewed from the top, the plurality of memory cells are arranged in a first area of the substrate, with the plurality of first via structures and the plurality of second via structures disposed in a second area and a third area of the substrate, respectively.

7. The memory device of claim 6, wherein the third area is located immediately next to the first area along a lateral direction, and the second area is located immediately next to the third area along the lateral direction.

8. The memory device of claim 7, wherein the first to fourth metal tracks all extend along the lateral direction.

9. The memory device of claim 5,
wherein the first access line further includes a plurality of third via structures electrically coupling the first metal track to the second metal track; and
wherein the second access line further includes a plurality of fourth via structures electrically coupling the third metal track to the fourth metal track.

10. The memory device of claim 9, wherein each of the first via structures is laterally aligned with a corresponding one of the third via structures, and each of the second via structures is laterally aligned with a corresponding one of the fourth via structures.

11. A semiconductor device, comprising:
a first memory array including a plurality of first memory cells arranged over a plurality of first columns and a plurality of first rows, wherein each of the plurality of first rows includes at least a first word line, and each of the plurality of first columns includes at least a first bit line and a first source line;
a first strap region disposed next to the first memory array along a lateral direction; and
a second strap region disposed next to the first strap region along the lateral direction;
wherein a plurality of first via structures are formed in the first strap region, and the plurality of first via structures are configured to electrically connect a first metal track and a second metal track operatively constituting at least a part of each of the first source lines; and
wherein a plurality of second via structures are formed in the second strap region, and the plurality of second via structures are configured to electrically connect a third metal track and a fourth metal track operatively constituting at least a part of each of the first bit lines.

12. The semiconductor device of claim 11, further comprising:
a second memory array including a plurality of second memory cells arranged over a plurality of second columns and a plurality of second rows, wherein each of the plurality of second rows includes at least a second word line, and each of the plurality of second columns includes at least a second bit line and a second source line;
a third strap region disposed next to the second memory array along the lateral direction; and
a fourth strap region disposed next to the third strap region along the lateral direction;
wherein a plurality of third via structures are formed in the third strap region, and the plurality of third via structures are configured to electrically connect a fifth metal track and a sixth metal track operatively constituting at least a part of each of the second source lines; and
wherein a plurality of fourth via structures are formed in the fourth strap region, and the plurality of fourth via structures are configured to electrically connect a seventh metal track and an eighth metal track operatively constituting at least a part of each of the second bit lines.

13. The semiconductor device of claim 12, wherein the first to fourth strap regions are interposed between the first memory array and the second memory array along the lateral direction.

14. The semiconductor device of claim 11, wherein the second metal track is disposed over the fourth metal track, the fourth metal track is disposed over the third metal track, and the third metal track is disposed over the first metal track.

15. The semiconductor device of claim 11, wherein the first to fourth metal tracks all extend along the lateral direction.

16. The semiconductor device of claim 11, wherein each of the plurality of first memory cells includes a transistor and a resistive element connected in series, and wherein the resistive elements of the plurality of first memory cells are vertically interposed between the third metal track and the fourth metal track.

17. A method for forming memory devices, comprising:
forming a plurality of transistors over a first region of a substrate, wherein the plurality of transistors operatively form portions of a plurality of memory cells, respectively; and
forming a plurality of metallization layers over the plurality of transistors;
wherein a first one of the plurality of metallization layers includes a first metal track, a second one of the plurality of metallization layers includes a second metal track, a third one of the plurality of metallization layers includes a third metal track, and a fourth one of the plurality of metallization layers includes a fourth metal track; and
wherein the first metal track and the second metal track are electrically connected to each other and collectively serve as a first access line for the plurality of memory cells, and the third metal track and the fourth metal track are electrically connected to each other and collectively serve as a second access line for the plurality of memory cells.

18. The method of claim 17, wherein the second metallization layer is disposed over the fourth metallization layer, the fourth metallization layer is disposed over the third metallization layer, and the third metallization layer is disposed over the first metallization layer.

19. The method of claim 17, further comprising:
forming, over a second region of the substrate, a plurality of first via structures each interposed between adjacent ones of the metallization layers, wherein the first via structures are configured to electrically coupe the first metal track to the second metal track; and
forming, over a third region of the substrate, a plurality of second via structures each interposed between adjacent ones of the metallization layers, wherein the second via structures are configured to electrically couple the third metal track to the fourth metal track;
wherein the second region is located next to the first region, and the third region is located next to the second region.

20. The method of claim 17, further comprising:
forming, over the first region, a plurality of resistive elements interposed between adjacent ones of the metallization layers;
wherein the plurality of resistive elements operatively form remaining portions of the plurality of memory cells, respectively.
